(19) United States
(12) Patent Application Publication
(10) Pub. No.: US 2018/0081075 A1
(43) Pub. Date: Mar. 22, 2018

(54) APPARATUS AND METHOD FOR COMPENSATING FOR RECEIVER MOTION IN AIRBORNE ELECTROMAGNETIC SYSTEMS

(71) Applicant: CGG SERVICES SAS, Massy Cedex (FR)

(72) Inventors: Adam SMIAROWSKI, Toronto, Ontario (CA); Philip MILES, Rockwood, Ontario (CA)

(73) Assignees: CGG SERVICES SAS, Massy Cedex (FR); CGG SERVICES SAS, Massy Cedex (FR)

(21) Appl. No.: 15/542,169

(22) PCT Filed: Dec. 16, 2015
(86) PCT No.: PCT/IB2015/002482

§ 371 Date: Jul. 7, 2017

Related U.S. Application Data
(60) Provisional application No. 62/112,724, filed on Feb. 6, 2015.

(51) Int. Cl. G01V 3/16; G01R 33/00; G01V 3/165

(52) U.S. Cl. CPC G01V 3/16; G01V 3/17; G01V 3/165; G01R 33/0029

(57) ABSTRACT

A computing device and method for removing noise associated with an excitation signal and its odd harmonics. A computing system for processing electromagnetic (EM) signals includes an interface that receives raw data indicative of a time rate of change of a magnetic field as recorded with a receiver coil while airborne, wherein the magnetic field includes a primary source excitation; and a processor connected to the interface. The processor is configured to calculate a rotation of the receiver coil relative to a desired orientation; derotate the raw EM data based on the rotation of the receiver coil relative to the desired orientation and on the primary source excitation, to obtain derotated EM data; and generate an image of a surveyed subsurface based on the derotated EM data.

### BACKGROUND

### Technical Field

Embodiments of the subject matter disclosed herein generally relate to methods and systems and, more particularly, to mechanisms and techniques for determining a motion of a receiver of an airborne electromagnetic (EM) system and compensating a measurement of the receiver for its motion.

### Discussion of the Background

EM surveying is a method of geophysical exploration to determine the properties of a portion of the earth's subsurface, information that is especially helpful in the oil and gas industry, geographic mapping, geologic mapping, mineral exploration, groundwater exploration and quality assessment, unexploded ordnance detection and characterization, engineering work, bathymetry, etc. EM surveys may be based on a controlled source, which sends a primary field into the earth. An EM survey may also be based on a natural source, in which case the primary field is the naturally generated magnetic field of the earth. By measuring the associated secondary fields with an EM receiver, it is possible to estimate the depth and/or location and/or composition of the subsurface features. These features may be associated with subterranean hydrocarbon deposits and/or mineral deposits.

An airborne EM survey system 100 generally includes, as illustrated in FIG. 1, a transmitter 102 for generating the primary EM field 104 that is directed toward the earth. When the primary EM field 104 enters the ground 108, it induces eddy currents 106 inside the earth. These eddy currents 106 generate a secondary electromagnetic field or ground response 110. An EM receiver 112 then measures the response 110 of the ground. Transmitter 102 and receiver 112 may be connected to a carrier 114, e.g., an aircraft, so that a large area of the ground is swept. Receiver 112 may be located concentric with transmitter 102. The currents induced in the ground are a function of the earth's conductivity and of course, the transmitter characteristics. By processing and interpreting the received signals, it is possible to study and estimate the distribution of conductivity in the subsurface. The distribution of conductivity is associated with the various layers 116 and 118 making up the subsurface, which is implicitly indicative of the location of oil and gas reservoirs, and/or other resources of interest for the mining industry.

Passive source EM surveying involves measurements where a receiver senses two or more components of a magnetic field, where the components are not necessarily measured at the same location. The magnetic field can be generated by naturally occurring random fluctuation of the earth's electromagnetic field or from a stationary transmitter located at some distance from the receiver. A frequency dependent transfer function of the measured components can be calculated and used to infer electrical property structure or geological structure of the earth.

For a number of reasons, it is often desirable to operate the surveying system with a wide-band of signal detection. Signal processing algorithms for EM data have developed over many years and there are numerous techniques available for removing noise in different parts of the frequency spectrum. Stacking algorithms have been developed to remove power line noise while simultaneously reducing random noise by averaging data samples. One issue limiting the low-frequency operation of airborne electromagnetic (AEM) systems is the receiver's rotation or oscillation in the natural magnetic field of the earth. As the receiver coil moves in the earth magnetic field, a low-frequency signal is created (according to Faraday's law), which can obscure the desired signal from the ground (Annan, 1983; Munkholm, 1997; Lo and Zang, 2008). This signal is often called coil motion noise.

Many systems employ a coil suspension system for the receiver coil to reduce the amplitude of this signal and to shift the frequency of the noise signal out of the band of the desired measurements. However, coil motion noise is still problematic when the receiver motion noise frequency content approaches the transmitter base frequency (Allard, 2007). Even with the suspension system, a data processing step is often required to remove noise caused by the receiver coil's motion. The suspension system essentially places a lower limit on the bandwidth of the AEM system.

Different techniques have been applied to remove coil motion noise. Munkholm attempted to project the measured x-, y- and z-component coil data into the direction of the earth's magnetic field where the coupling of coil vibrations is minimal. Spies (1990, U.S. Pat. No. 4,945,309) describes a method in which motion noise is monitored with a motion sensor; if the motion noise exceeds some threshold value over some interval, that portion of the signal record is removed. Kuzmin and Dodds (2014, U.S. Pat. No. 8,878,538 B2) describe a system where the receiver coil orientation is measured and the noise caused by changes of the orientation of the receiver coils in the earth's static magnetic field are subtracted. Harbaugh et al. (2010) describe using global positioning systems (GPS) and inertial measurement unit (IMU) sensors to measure the vibration and motion of the receivers in a ground system and presented the equations necessary to calculate the voltage caused by these motions. Harbaugh et al. also compared the measured noise and the noise modelled using the IMU measurements of receiver motion.

Allard illustrates an example of using a quasi-linear function to approximate the slowly-oscillating baseline that results from coil motion noise. Kingman (2004) describes using a tapered stacking approach to remove linear drift in data, which is called a tapered Halverson stacking filter. This filter is effective at removing coil motion noise because its low-frequency part is approximately linear. Allard also states that coil motion noise can be approximated by a quasi-linear function. Similarly, Smiarowski (2013) removed coil motion oscillation noise by subtracting the running average of the continuously streamed measured signal over four transmitter half-cycles. Fugro-TEMPEST (2007) acquisition and processing reports describe a process to remove coil motion noise below the transmitter base frequency by applying a tapered stack. The Fugro processing report recognizes that this process has difficultly removing coil motion rotation noise at the base frequency.

Thus, the existing methods and devices do not fully correct the coil motion noise. Therefore, there remains a need for an improved algorithm for correcting raw EM data affected by the receiver coil's motion.

### SUMMARY

According to one embodiment, there is a computing system for processing electromagnetic (EM) signals. The computing system includes an interface that receives raw data indicative of a time rate of change of a magnetic field as recorded with a receiver coil while airborne, wherein the magnetic field includes a primary source excitation; and a processor connected to the interface. The processor is configured to calculate a rotation of the receiver coil relative to a desired orientation; derotate the raw EM data based on the rotation of the receiver coil relative to the desired orientation and on the primary source excitation, to obtain derotated EM data; and generate an image of a surveyed subsurface based on the derotated EM data.

According to another embodiment, there is a method for processing electromagnetic (EM) signals. The method includes receiving raw data indicative of a time rate of change of a magnetic field as recorded with a receiver coil while airborne, wherein the magnetic field includes a primary source excitation; calculating a rotation of the receiver coil relative to a desired orientation; derotating the raw EM data based on the rotation of the receiver coil relative to the desired orientation and on the primary source excitation, to obtain derotated EM data; and generating an image of a surveyed subsurface based on the derotated EM data.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a schematic diagram of an EM acquisition system;

FIG. 2A illustrates the noise induced by the modulation of the transmitter base frequency, FIG. 2B illustrates a correction signal, and FIG. 2C shows the corrected signal;

FIG. 3 shows the frequency power spectra for the raw signal;

FIG. 4 shows the frequency power spectra for the corrected signal;

FIG. 5 shows an estimated coil orientation based on a primary field of the transmitter coil;

FIG. 6 shows the corrected signal after derotation;

FIG. 7 shows the frequency spectra of a derotated signal;

FIG. 8 shows the frequency spectrum computed from measurements of the earth's magnetic field using a stationary coil;

FIG. 9 shows a simulation of the effect that an oscillating coil has on the frequency power spectrum that would be calculated from the coil sensor signal;

FIG. 10 illustrates an AEM system that is capable of correcting the noise associated with the receiver coil's rotation;

FIG. 11 is a flowchart of a method for correcting the noise associated with the receiver coil's rotation; and

FIG. 12 is a schematic diagram of a computing device that can run various methods discussed herein.

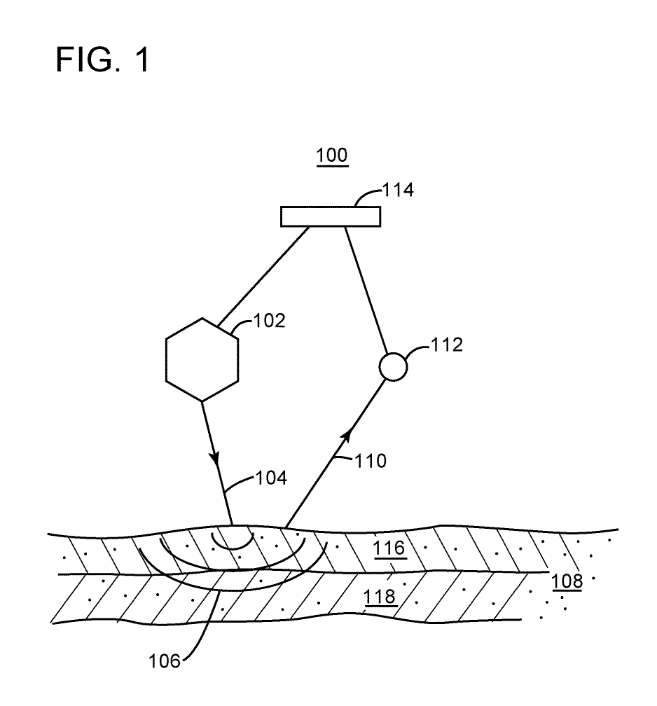

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of an AEM system having a receiver coil and a transmitter coil. However, the embodiments to be discussed next are not limited to this configuration; they may be applied to configurations having only receiver coils and no transmitter coils.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

As discussed in the Background section, receiver motion noise for an AEM receiver is caused by motion of the receiver coil in the static geomagnetic field. However, this is not the only source for receiver motion noise. The present inventors have observed that motion or rotation of the receiver in the excitation magnetic field (i.e., the primary magnetic field for a controlled source) also generates noise. The existing coil suspension systems reduce the frequency of receiver motion, but this results in a modulation effect of the excitation signal such that energy from the excitation frequency is leaked into sidebands around the spectral peak according to the suspension frequency.

The following experiment has been performed by the inventors to elucidate this modulation problem. In the experiment, a receiver coil was placed near a transmitter coil. The transmitter coil has been configured to generate a half-sine rectified waveform (excitation signal) with a transmitter base frequency of 30 Hz. The pulsed nature of the transmitter results in a time-varying magnetic field which is sensed by the receiver coil.

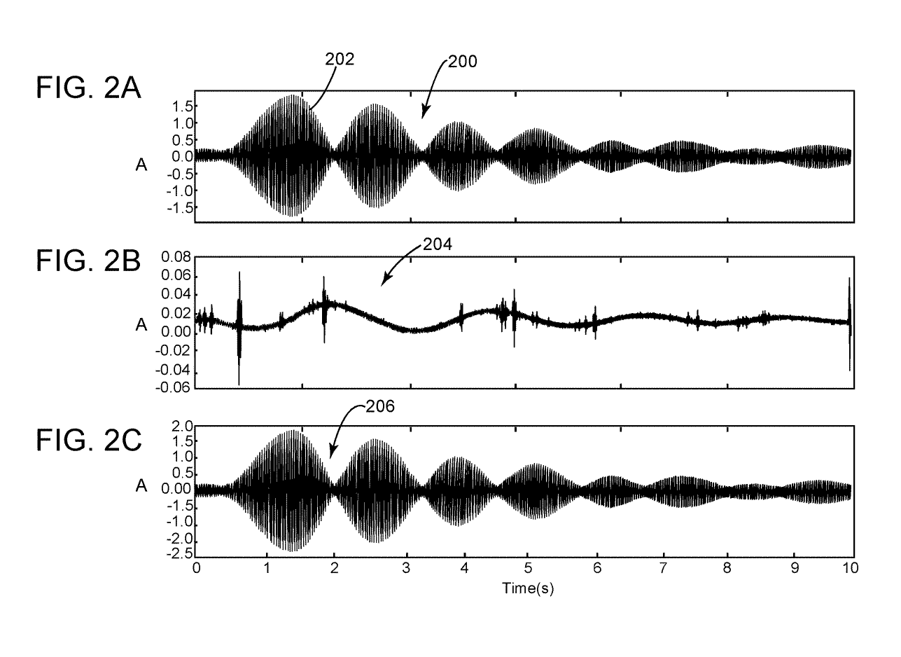

FIG. 2A shows 10 seconds of a raw measured signal 200 (the secondary magnetic field) in response to the excitation (primary magnetic field) from the controlled source, where a receiver coil rotates relative to the primary magnetic field. FIG. 2A shows that at about 0.5 seconds, the receiver coil was made to oscillate. The rotation frequency, controlled by the suspension system, is about 0.4 Hz. Lobes 202 seen in FIG. 2A are due to the changing coupling between the transmitter coil and receiver coil as the receiver coil rotates. The suspension system absorbs the rotation energy slowly, attenuating the amount of rotation, which explains why the lobe amplitude 202 decreases toward the end of the raw signal trace 200.

FIG. 2B shows a linear drift correction term 204 calculated using the Halverson filter. Note that the correction term 204 consists mainly of low frequency signals, which may be in the DC to 20 Hz range. FIG. 2C shows the corrected signal 206, i.e., the measured signal 200 after being corrected with the correction term 204. The correction term 204 has only corrected noise caused by the rotation of the coil in the earth's magnetic field and has not removed the effect of rotation in the transmitter magnetic field. This means that the Halverson filter has not corrected the modulation of the secondary signal, which can also be considered an excitation signal from the perspective of the receiver.

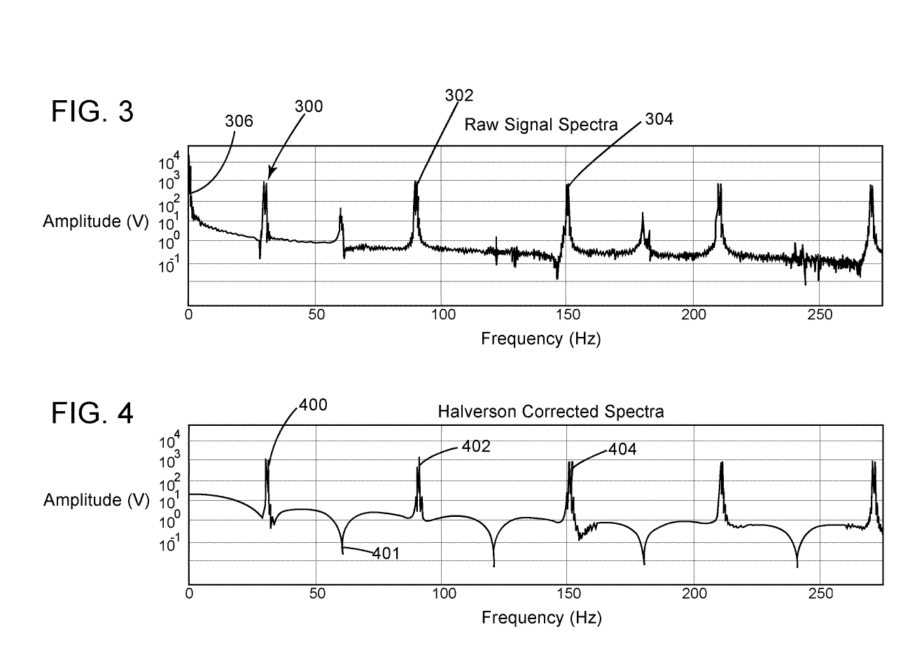

The frequency amplitude spectrum for the raw signal 200 is shown in FIG. 3, which illustrates the signal component 300 from the 30 Hz base frequency and its odd harmonics 302, 304, etc. The spectral lines are not sharp spikes because the coil rotation has modulated the transmitter signal into the sidebands above and below the base frequency 300 and its odd harmonics 302, 304, etc. FIG. 3 also illustrates the low-frequency energy 306 below the base frequency 300, from DC to 30 Hz, which is due to the rotation of the receiver coil in the earth's magnetic field. FIG. 4 shows the frequency spectra after application of the Halverson stacking filter signal (frequency spectra for the signal shown in FIG. 2C). The powerline frequency 401 of 60 Hz is greatly reduced compared to the raw spectrum in FIG. 3. Also, the low-frequency noise caused by coil rotation in the band from DC to 15 Hz has also been greatly reduced. However, the modulation of the base frequency 400 and its odd harmonics 402 and 404 caused by coil rotation in the transmitter magnetic field is still present.

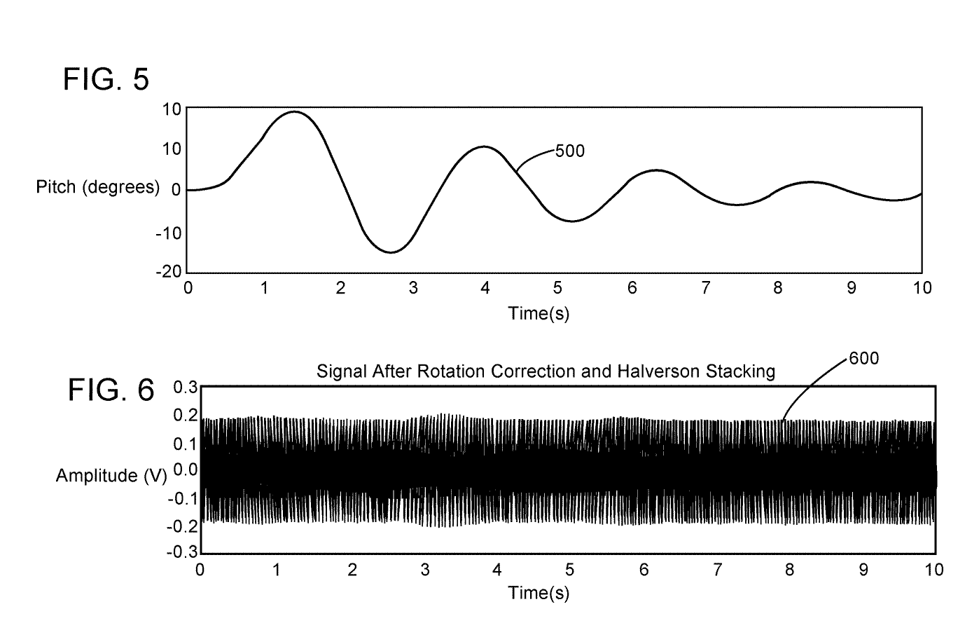

It is possible to correct the effect of coil oscillation (e.g., Sheldrake (2005) for fixed-wing EM and Fugro-Heligeotem (2007) for a helicopter system) in the magnetic field of the earth as now discussed. Using an assumption that the relative transmitter-receiver position is known, the transmitter on-time signal is used as an estimate of the primary field from the transmitter. This estimate of the primary field is then used in an inversion algorithm to estimate the coil orientation relative to the transmitter. However, these corrections are not accurate in areas with conductive features (i.e., underground formations that conduct electric charges) as the assumption that the on-time signal consists mainly of the primary magnetic field may not be valid, which results in uncertainty and error in the estimated orientation of the receiver coil as disclosed in Smith, 2001, and Vrbancich and Smith, 2005. FIG. 5 shows the estimated receiver coil orientation using the measured raw signal 200 from FIG. 2A. FIG. 5 shows only the pitch 500, but roll and yaw can also been computed.

After determining the orientation of the receiver coil, the raw measured signal 200 can be rotated to determine the signal that would have been measured if the coil set was oriented in the desired orientation. This process of correcting the raw signal is referred to as “derotation” and it may be performed by using standard Euler angle rotation matrices and the estimated pitch, roll and yaw angles. The derotation correction can be applied to the recorded data before or after stacking.

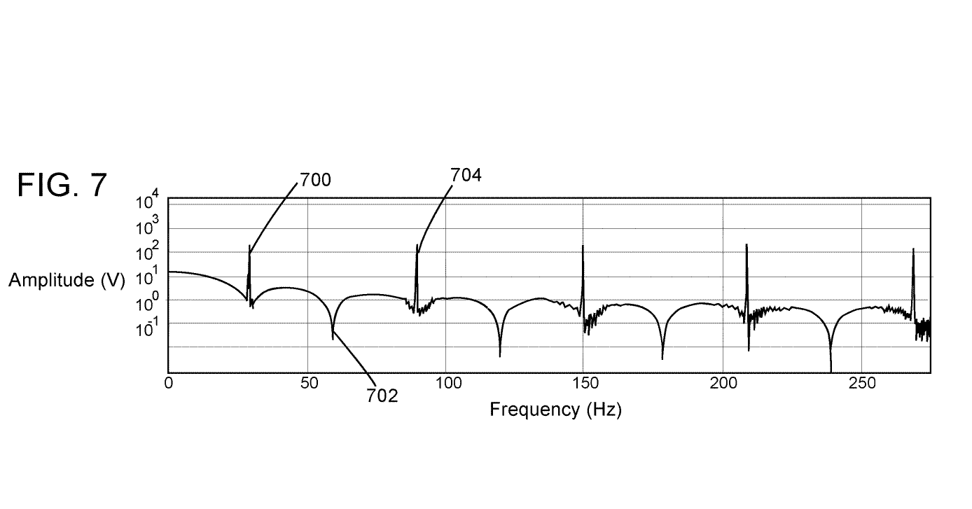

The Halverson stacking filter removes noise caused by receiver coil's rotation in the earth's geomagnetic field, power line noise and white stochastic noise, as illustrated in FIG. 6. FIG. 6 shows the derotated signal 600 after the rotation correction and the Halverson stacking filter have been applied. Note that much of the rotation modulation 202 has been removed and the peak amplitude from the primary field is nearly uniform. FIG. 7 shows the frequency spectra of the derotated signal 600. It can be seen that the sidebands around the base frequency 700 and its odd harmonics 702, 704 caused by the receiver coil's rotation has been reduced.

While the rotation correction algorithm discussed above is useful, it is desirable to further reduce the noise corresponding to the sidebands and obtain lower noise levels. Also, if conductive material is located underground nearby the surface, this results in an on-time response, which makes the assumption that the on-time signal consists of only the primary magnetic field from the transmitter to be invalid.

The above example has been discussed for a controlled source EM system with a single transmitter operating at a single frequency. If multiple transmitters are employed, there will be a similar modulation effect dependent on the transmitter base frequency and direction of the transmitted field.

Different from the controlled source EM systems, natural source EM systems use the naturally occurring random fluctuations of the earth's geomagnetic field as an excitation source (i.e., primary signal). Passive EM systems use the same source as natural source systems, but may also use man-made sources not controlled by the system, such as very low-frequency (VLF) signals or other communication signals. In natural and passive systems, the source signal very often is not comprised of a single excitation frequency. The source spectrum for natural source fields has been demonstrated by numerous authors (Bleil, 1964; Galejs, 1965; Hoover et al, 1978; Labson et al, 1985).

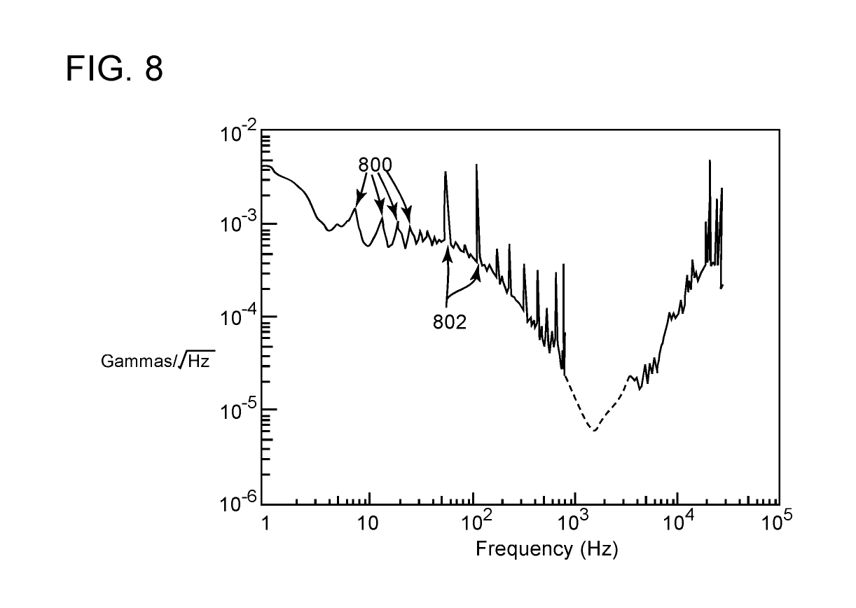

In this respect, FIG. 8 shows the frequency spectrum computed from measurements of the earth's magnetic field using a stationary coil (Labson, 1985). The peaks 800 in the range 3-60 Hz are centered on the Schumann resonance frequencies, which are a set of spectrum peaks in the extremely low-frequency band that result from the ionosphere acting like a waveguide. The frequencies of these peaks were predicted by Schumann (1952) to occur at:

$${f}_{n} = \frac{c}{2 π a} \sqrt{n ( n + 1 )} ,$$

where fn is the resonant frequency of the nth mode, c is the speed of light and a is the radius of the earth.

The fundamental resonance occurs at 7.83 Hz, with Schumann peaks also occurring at 14.3, 20.8, 27.3 and 33.8 Hz. The frequency of the peak can shift depending upon ionospheric-earth conditions (Yatsevich et al, 2008) and are not a single spectral line but show spectral width because of a dissipative effect in the ionosphere.

FIG. 8 also shows the power-line frequencies 802. Not shown in this figure is the amplitude of the DC or 0 Hz component of the earth's magnetic field, which is shaped similarly to a dipole situated close to the center of the earth. This results in the magnetic field at the poles being stronger than the field at the equator. Rotations of a receiver in the earth's DC magnetic field are also a concern for electromagnetic methods but can be corrected using the methods described previously (including stacking, running average filtering or use of a quasi-linear function).

For the case of a passive or natural electromagnetic system, the receiver coil rotation will result in the modulation of every natural or passive source frequency. Note that the controlled source electromagnetic system described in the above example utilizes a particular waveform with an “on-time” period where a primary magnetic field is being generated as well as an “off-time” period where no field is generated. In passive or natural sources, the excitation signal is always active (even if low amplitude) and can be decomposed into sinusoidal signals. The primary magnetic field is used herein as a generic term that refers to the controlled source excitation, or natural source excitation or the passive source excitation.

The receiver coil rotation modulates the spectrum of naturally occurring excitation frequencies and the secondary signal they cause in the ground in a similar manner to the controlled source case outlined above. Thus, it is desirable to correct for the modulation effect caused by the rotation of the receiver coil set in the earth's fluctuating magnetic field and the resultant secondary field.

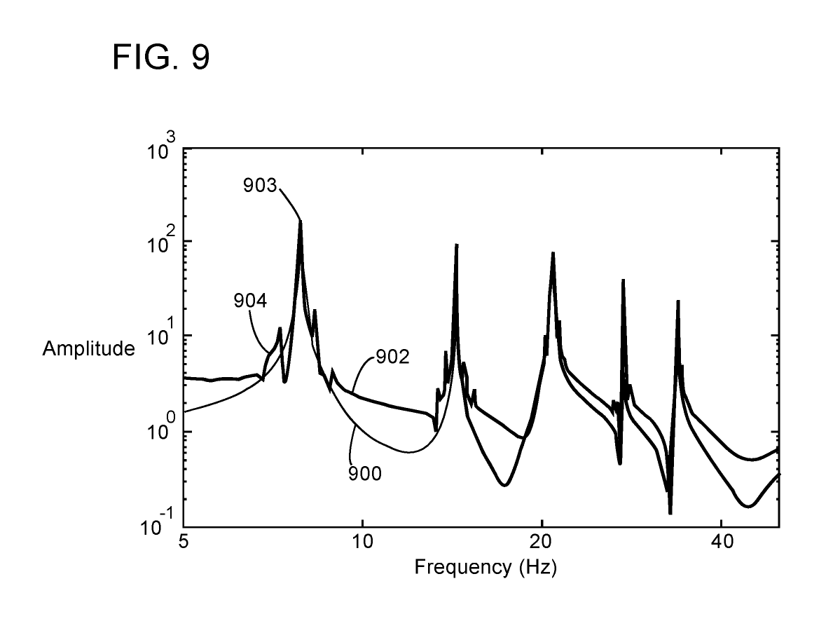

FIG. 9 shows a simulation of the effect that an oscillating coil has on the frequency power spectrum that would be calculated by the receiver coil. The primary magnetic field consists of the earth's static geomagnetic field and the naturally-occurring random fluctuations of the magnetic field and has components in the horizontal and vertical directions. Because an induction coil sensor measures the time-rate of change of a magnetic field, if the induction coil sensor is stationary, it is blind to the static geomagnetic field. A stationary magnetometer, however, would sense the static component as well. A stationary coil sensor shows energy at the Schumann resonance frequencies, as indicated by line 900 in FIG. 9. The frequency power spectrum computed from an oscillating coil in the same magnetic field is shown as line 902 in FIG. 9 and it shows the sidebands 904.

An oscillating coil sensor results in a change in coupling to the earth's magnetic field, which is a vector. A change in coupling results in a change in the magnetic flux through the coil, which, according to Faraday's Law, causes a voltage, referred to here as a signal. A vertical coil is cosine coupled to the vertical component of a magnetic field and sine coupled to a horizontal magnetic field. An oscillating coil will result in modulation of the excitation signal because of the change in coupling at the coil oscillation rate (due to sine-coupled component) and at twice the oscillation rate (due to the cosine coupled component). Sensor rotation also modulates the amplitude of the spectral line. While FIG. 9 shows the modulation of the amplitude of the spectral line to be minor, the secondary fields of interest are small compared to the excitation signal and a correction of this effect can be important in some cases. More specifically, FIG. 9 shows a comparison of frequency power spectra of a stationary coil measuring the magnetotelluric earth field (line 900) and power spectra for a coil sensor oscillating at 0.5 Hz. The peaks at the Schumann resonance frequencies can be seen. The peaks at rotation frequencies 0.5 Hz and 1 Hz are due to the coil rotating in the earth's static magnetic field. The coil rotation modulates the Schumann frequencies, which results in an error in measurement of the amplitude of the Schumann resonances 903 and also results in the sidebands 904 around the spectral lines

According to an embodiment, a process is introduced that measures the coil orientation and applies a correction to account for the effect of coil's motion on the coupling between the receiver and various sources which affects the magnetic flux through the coil. Therefore, this process reduces the modulation effect. The excitation signal may be from natural fluctuations of the earth's magnetic field or from a controlled transmitter or from a remote uncontrolled (by the survey system) transmitter. The signal caused by rotation of the coil in the earth's static geomagnetic field can be removed through other means, such as those described previously, including the Halverson stacking filter, which is effective at removing low-frequency noise due to rotation of a sensor in the earth's static geomagnetic field, or a running average filter, or a quasi-linear function to estimate and remove the baseline introduced by coil oscillation.

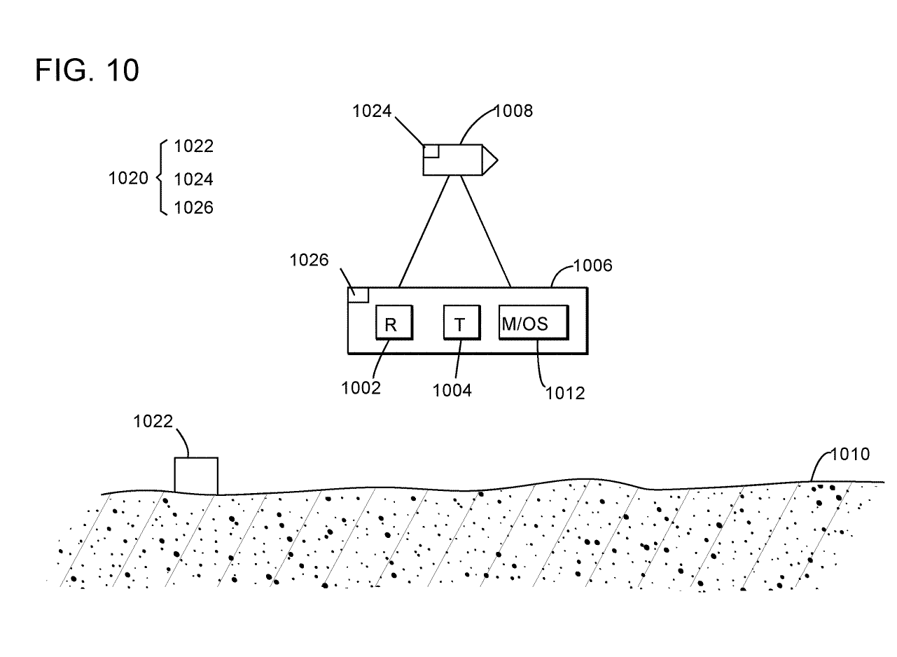

According to an embodiment, it is desired to correct (i) receiver or (ii) transmitter and receiver motion in EM systems for the noise caused by their motion. These systems typically contain two or three receivers, which may or may not be identical in terms of configuration or area. Typically, the receivers are arranged to be oriented orthogonally to one another, as for example, in U.S. Ser. No. 14/678,228 (the '228 application herein). However, this is not a necessity. In airborne systems, as illustrated in FIG. 10, the receiver coils 1002 and transmitter coils 1004 are typically attached to a platform 1006, which is towed by an aircraft 1008. Aircraft 1008 can be a fixed-wing aircraft, helicopter, airship, blimp, dirigible, hybrid aircraft, balloon or similar. AEM system 1000 is shown flying over ground 1010. To explore at a desired depth, AEM systems often employ low-excitation frequencies but, as identified by many in the industry, the issue of coil motion noise in the earth's static geomagnetic field increases noise levels at low-frequencies such that the noise level greatly exceeds the desired signal.

In the experience of the inventors, the tapered Halverson stacking filter is effective at removing noise caused by low-frequency coil motion in the earth's static geomagnetic field. However, the stacking filter approach does not remove the modulation of the base frequency caused by the receiver coil's motion or coil rotation, which results in relatively large amplitude sidebands around the base frequency and its odd harmonics. A similar effect occurs when natural or passive magnetic fields are used as the excitation sources. These sidebands increase the noise level of the electromagnetic system. Thus, according to embodiments to be discussed herein, a system and method to measure a rotation signal proportional to the motion or rate of change of motion or orientation or rate of change of orientation of a receiver coil set (which consists of at least one coil) are used. A motion and/or orientation system 1012 (called herein rotation system) may be attached to the platform 1006 for measuring the rotation signal. The measured rotation signal is used then by a controller 1020 to determine a “derotated signal,” which is the signal that would be recorded by the receiver coil if it were positioned and oriented at the time of measurement in the desired position and orientation, which for example, could be with one coil oriented straight up and down (i.e., along the earth's gravity field) and a second coil oriented along the flight line.

Controller 1020 may have a component 1022 located on the ground, a component 1024 located on the airplane 1008 and/or a component 1026 located on the platform 1006. Those skilled in the art would understand that controller 1020 may include one or more of components 1022, 1024, and 1026. In one application, each component 1022, 1024, and 1026 includes a transceiver for communicating (in a wireless manner) with the other components. In one application, the controller is made up of only the ground component 1022, and data collected from rotation system 1012 is supplied after the survey to the ground component 1022 for calculating the receiver's rotation. Note that the receiver rotation may be related to the position and/or orientation of its coils.

The receiver's desired orientation is not critical, but only needs to be specified. The desired position is usually determined by the structure of the electromagnetic system. Use of the “derotated signal” corrects for noise caused by the modulation effect resulting from the receiver coil set sensing the magnetic field generated by the transmitter (i.e., primary magnetic field) or natural fluctuations of the earth's geomagnetic field while the receiver coil set is in an altered position or altered orientation away from the desired position or desired orientation. Use of the “derotated signal” allows for the sidebands, resultant from modulation of the transmitter base frequency and its odd harmonics by motion or rotation of the receiver coil set in the magnetic field generated by the transmitter, to be reduced in amplitude.

After the “derotated signal” is calculated (various methods for calculating the derotated signal to be discussed later), a stacking filter or quasi-linear function or running average filter or some other processing method such as those described in the Background section can be used to estimate and remove the noise signal caused by motion or rotation of the coil set in the earth's static geomagnetic field.

There are a number of different methods and procedures that can be used to generate a signal proportional to the motion or rate of change of motion or orientation or rate of change of orientation of the receiver coil set. This list is not exhaustive, but it is intended to indicate possible instruments and methods that can be used to determine motion and/or orientation of the receiver coil set. Kratzer and Vrbancich (2007) used GPS sensors and inertial navigation units (INU) to provide independent measures of the attitude of a receiver platform. Reid (2010) describes use of inclinometers to measure transmitter pitch and roll. Gyroscopes, accelerometers or angular rate sensors can be used to measure the transmitter or receiver orientation. There also exist optical/video tracking instruments, laser instruments, Attitude Heading Reference Systems (AHRS), inertial measurement units, infrared motion detection, to measure orientation and/or position. Another method to measure receiver coil set orientation and/or location is described in the '228 application. Macnae and Smiarowski (2007) used GPS measurements to measure the relative positions of the transmitter coil and receiver coil set as well as the orientation of the transmitter coil. Any of the devices noted above with regard to the method for obtaining a signal proportional to the motion or rate of change of motion or orientation or rate of change of orientation of the receiver coil set, may be part of the motion and/or orientation system 1012.

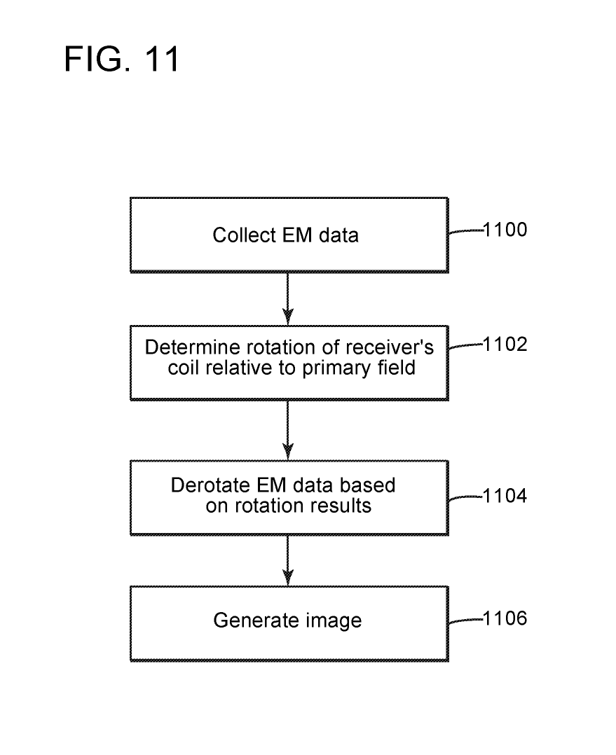

A method for correcting a recorded EM signal is now discussed with regard to FIG. 11. In step 1100, EM data is collected with an AEM system. Alternatively, the EM data is received from an existing AEM survey. The EM data is collected with an AEM system including at least transmitter coil(s) and receiver coil(s). Additional sensors may be employed to determine the orientation of the coils relative to the gravity vector (i.e., a Cartesian coordinate system). Further additional sensors may be employed to determine the relative position between the transmitter coil(s) and receiver coil(s).

In step 1102, a rotation of the receiver coil relative to a desired orientation is determined. This step takes place in a computing device, for example, controller 1020 discussed above. This step can take place while the EM data is collected, or after the AEM survey has concluded. There are many methods for determining the receiver coil rotation relative to the desired orientation. However, the method discussed above about using the primary field for determining the rotation of the receiver's coil is unsatisfactory and should be avoided. While the Halverson stacking filter is effective at removing noise caused by movement and rotation of the receiver coil(s) in the earth's magnetic field, the stacking process does not remove the modulation of the transmitter's primary signal by the rotation of the receiver coil(s), which results in sidebands forming around the transmitter base frequency and its odd harmonics. These sidebands are not adequately removed by traditionally employed algorithms which estimate receiver rotation by using the estimated transmitter primary field and assuming the relative offset between transmitter coil(s) and receiver coil(s).

Step 1102 may be accomplished by measuring the orientation of the receiver coils (or angular rate of change) and/or the displacement of the coils relative to the primary magnetic field. Based on this step, the measured raw signal (i.e., collected EM data) is derotated in step 1104 and the energy associated with the sidebands of the modulated transmitter base frequency and its odd harmonics is removed. In one application, knowing the transmitter base frequency helps in deciding how well the rotation of the receiver need to be measured. This information may be received in step 1100 as for an active system the operator controls the transmitter base frequency. Methods for measuring the location and/or orientation of the primary magnetic field are known in the art and not repeated herein. In step 1106, an image of the surveyed subsurface is generated based on the derotated EM data.

The method discussed above is also applicable to passive or natural source EM systems with minor modifications. For example, for a natural source EM system, the excitation signal is the naturally occurring fluctuations of the earth's geomagnetic field, and the desired secondary signal from the ground will be at the same frequencies (and odd harmonics) as the naturally occurring fluctuations. A rotation of the receiver coil(s) modulates the excitation signals by the rotation frequency of the coil set resulting in sidebands forming around the frequency of the excitation signals and their odd harmonics. Stacking the raw signal will not remove these sidebands. By measuring the orientation and/or motion of the receiver coils relative to the desired orientation, the measured signal can be derotated before stacking, which will reduce or eliminate the modulation of the desired frequencies and the associated sidebands. Note that a land site may be used as reference to obtain the instantaneous amplitude of the horizontal components of the naturally occurring fluctuations of the geomagnetic field in the x and y directions.

In another example of the application of the method illustrated in FIG. 11, a passive source EM system is considered. The excitation signal can be the naturally occurring fluctuations of the earth's magnetic field or sferic events (a sferic event is a broadband electromagnetic impulse that occurs as a result of natural atmospheric lightning discharges) transmitted by the earth's ionosphere or can also include active transmitters located away from the survey site, such as stationary wire loops on the ground or VLF transmitters operating at a single excitation frequency. The excitation signal from these sources is generally sinusoidal. From these passive or natural sources, there may be a number of discrete frequencies which act as the excitation signal for the EM system. Rotation and/or motion of the receiver coil results in modulation of the excitation sources and results in sidebands occurring at each of the excitation frequencies and their odd harmonics.

Note that the direction of the receiver coils relative to the excitation sources may be different for the various excitation frequencies. If the direction to the various sources is not the same, the amount of modulation of the excitation signal caused by receiver rotation is different for each excitation source.

There are many possible implementations of the method discussed above. One EM system that provides sufficient information for practicing the method discussed above may include components for determining the position and/or orientation of the receiver, a three-component receiver and a three-component transmitter. The EM system may include other peripheral sensors to determine the position or orientation or state of the electromagnetic measurement, such as Global Positioning System (GPS), radar or laser altimeter, gyroscopes or inclinometers measuring transmitter or sensor positions, thermometers for measuring the ambient temperature and/or the receiver coil's temperature, or other sensors measuring other geophysical data (such as radar or laser for topography, gravity or gradiometers sensors, spectrometer sensors, magnetometers to measure the ambient earth magnetic field, etc.). Consequently, there are also many different methods to record, process, combine and control all of these signals and sensors.

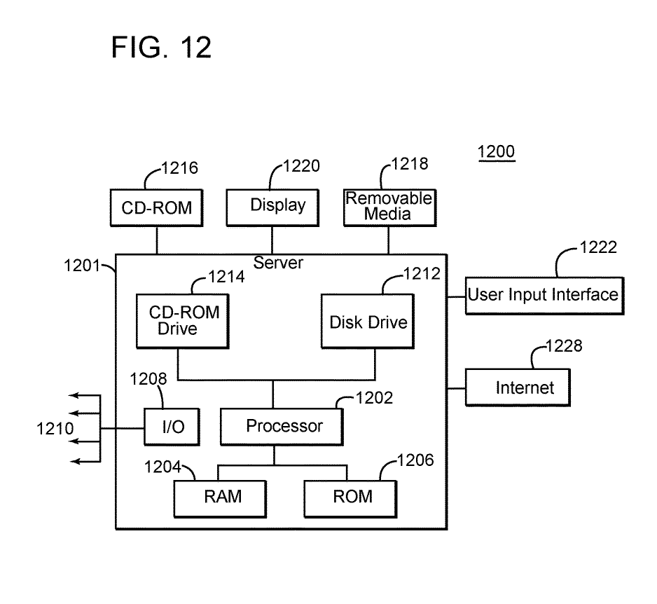

The steps discussed above with regard to FIG. 11 may be implemented in a processing device. An example of a processing device capable of carrying out operations in accordance with the embodiments discussed above is illustrated in FIG. 12. Such processing device may be located on the aircraft, tow assembly, transmitter section, receiver section, in a research facility, distributed at multiple sites, etc. Hardware, firmware, software or a combination thereof may be used to perform the various steps and operations described herein.

The exemplary processing device 1200 suitable for performing the activities described in the exemplary embodiments may include server 1201. Such a server 1201 may include a central processor unit (CPU) 1202 coupled to a random access memory (RAM) 1204 and/or to a read-only memory (ROM) 1206. The ROM 1206 may also be other types of storage media to store programs, such as programmable ROM (PROM), erasable PROM (EPROM), etc. Processor 1202 may communicate with other internal and external components through input/output (I/O) circuitry 1208 and bussing 1210, to provide control signals and the like. For example, processor 1202 may communicate with the various EM receivers, transmitters, etc. Processor 1202 carries out a variety of functions as are known in the art, as dictated by software and/or firmware instructions.

Server 1201 may also include one or more data storage devices, including disk drives 1212, CD-ROM drives 1214, and other hardware capable of reading and/or storing information, such as a DVD, etc. In one embodiment, software for carrying out the above-discussed steps may be stored and distributed on a CD-ROM 1216, removable media 1218 or other form of media capable of storing information. The storage media may be inserted into, and read by, devices such as the CD-ROM drive 1214, disk drive 1212, etc. Server 1201 may be coupled to a display 1220, which may be any type of known display or presentation screen, such as LCD, plasma display, cathode ray tube (CRT), etc. A user input interface 1222 is provided, including one or more user interface mechanisms such as a mouse, keyboard, microphone, touch pad, touch screen, voice-recognition system, etc.

Server 1201 may be coupled to other computing devices, such as the equipment of the carrier, via a link or network. The server may be part of a larger network configuration as in a global area network (GAN) such as the Internet 1228, which allows ultimate connection to the various landline and/or mobile devices involved in the survey.

As also will be appreciated by one skilled in the art, the exemplary embodiments may be embodied in a wireless communication device, a telecommunication network, as a method or in a computer program product. Accordingly, the exemplary embodiments may take the form of an entirely hardware embodiment or an embodiment combining hardware and software aspects. Further, the exemplary embodiments may take the form of a computer program product stored on a computer-readable storage medium having computer-readable instructions embodied in the medium. Any suitable computer-readable medium may be utilized, including hard disks, CD-ROMs, digital versatile discs (DVD), optical storage devices or magnetic storage devices such as a floppy disk or magnetic tape. Other non-limiting examples of computer-readable media include flash-type memories or other known types of memories.

This written description uses examples of the subject matter disclosed to enable any person skilled in the art to practice the same, including making and using any devices or systems and performing any incorporated methods. For greater clarity, the figures used to help describe the invention are simplified to illustrate key features. For example, figures are not to scale and certain elements may be disproportionate in size and/or location. Furthermore, it is anticipated that the shape of various components may be different when reduced to practice, for example. The patentable scope of the subject matter is defined by the claims, and may include other examples that occur to those skilled in the art. Such other examples are intended to be within the scope of the claims. Those skilled in the art would appreciate that features from any embodiments may be combined to generate a new embodiment.

The disclosed embodiments provide a method and processing device capable of derotating a raw signal for removing noise associated with a modulation of various excitation signals and associated harmonics. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

Allard, M., 2007. On the Origin of the HTEM Species, “Proceedings of Exploration 07: Fifth Decennial International Conference on Mineral Exploration”, edited by B. Milkereit, paper 21, 355-374.
Annan, P., 1983. Effect of differential transmitter/receiver motion on airborne transient E M interpretation, 53rd Annual International Meeting of the Society of Exploration Geophysics, Expanded Abstracts, 622-623.
Bleil, D. F., 1964. Natural electromagnetic phenomena below 30 kcs. New York, Plenum Press.
Galejs, J., 1965, Schumann resonances. [U.S.] National Bureau of Standards Journal Research, v. 69D, 1043-1056.
Fugro-Heligeotem, 2007. Fugro Airborne Surveys Logisitics and Processing Report, Airborne Magnetic and HeliGEOTEM II Survey, Schultz Lake Area, Baker Lake, Nunavut, Agnico-Eagle Mines Ltd., 2007.
http://www.cngo.ca/data/exploration_reports/085/0852/085295/Digital_Data/Fugro/07304_{—} report_Schultz_Lake. pdf Accessed Jan. 21, 2015.
Fugro-TEMPEST, 2007. Baron-Hay, S. and Stenning, L. Alice Springs, Northern Territory TEMPEST Geophysical Survey, Acquisition and Processing Report for NuPower Resources Limited. 2007.
http://geoscience.nt.gov.au/gemis/ntgsjspuVbitstream/1/75723/2/EL25338_2010_P_02_18 85_tempest_report.pdf Accessed Jan. 21, 2015.
Harbaugh, G. R., Steinhurst, D. A., Howard, M., Barrow, B. J., Miller, J. T. and Bell, T. H., 2010. Quantification of Noise Sources in EMI Surveys, Technology Demonstration-Report, Army Research Laboratory, Blossom Point, Md., July-September 2006. Naval Research Laboratory, Jan. 14, 2010.
Hoover, D. B., Long, C. L and Senterfit, R. M., 1978. Some results from audio magnetotelluric investigations in geothermal areas. Geophysics, 43, 1501-1514.
Kingman, J. E. E., Halverson, M. and Garner, S. J., 2004. Stacking of Controlled Source Electrical Geophysical Data. Terrigena Technical White Paper Number 20040328.0101(e). http://www.terrigena.com/images/stories/pdf/Terrigena.0101%28e %29.Stacking.USLetter. pdf (password is terrigena.com). Accessed Jan. 20, 2015.
Kratzer, T. and Vrbancich, J., 2007. Real-time kinematic tracking of towed AEM birds. Exploration Geophysics, 38, 132-143.
Kuzmin, P. V. and Dodds, J., Reciever Coil Assembly For Airborne Geophysical Surveying with Noise Mitigation, U.S. Pat. No. 8,878,538 B2, Nov. 4, 2014, Filed Nov. 26, 2010
Labson, V. F., Becker, A., Morrison, H. F. and Conti, U. 1985. Geophysical exploration with audiofrequency natural magnetic fields. Geophysics, 50, 4, 656-664.
Lo, B., and Zang, M., 2008. SEG Las Vegas 2008 Annual Meeting
Macnae, J. and Smiarowski, A., 2007. Airborne detection of perfect conductors: Project Gemini, “Proceedings of Exploration 07: Fifth Decennial International Conference on Mineral Exploration”, edited by B. Milkereit, paper 23.
Munkholm, M. S., Motion-induced noise from vibration of a moving TEM detector coil: characterization and suppression, Journal of Applied Geophysics, 36, 1997, 21-29.
Reid, J., 2010. An overview of the SkyTEM airborne EM system with Australian examples, Preview, 145, 26-37.
Schumann, W. O. 1952. Uber die strahlungslosen Eigenschwingungen einer leitenden Kugel, die von einer Luftschicht und einer lonospharenhulle umgeben ist. Zeitschrift und Naturfirschung 7a. 149-154.
Sheldrake, R. F., 2005. Geophysical Report: MEGATEM II Electromagnetics Survey on the Foy Offset Dyke Properties Sudbury Basin Mining District, Ontario NTS:41I for Tearlach Resources Limited, 2005. http://www.geologyontario.mndmf.gov.on.ca/mndmfiles/afri/data/imaging/20000000547//20001386.pdf

### Accessed Jan. 22, 2105.

Smiarowski, A. and Macnae, J., 2013. Detection of a perfect conductor with an airborne electromagnetic system: The Gemini Field Test. Geophysics, 78,5, E249-E259.
Smith, R. S., 2001, Tracking the transmitting-receiving offset in fixed-wing transient E M systems: methodology and application, Exploration Geophysics, 32, 014-019.
Spies, B. R., 1990. Method of Reducing Impulsive Noise in Electromagnetic Geophysical Data, U.S. Pat. No. 4,945,309, Filed Aug. 14,1989, Date Jul. 31,1990.
Vrbancich, J. and Smith, R., 2005. Limitations of two approximate methods for determining the AEM bird position in a conductive environment. Exploration Geophysics, 36: 365-373.
Yatsevich, E. I. and Nickolaenko, A. P. and Pechnaya, O. B., 2008. Diurnal and seasonal variations in the intensities and peak frequencies of the first three Schumann-resonance modes. Radiophysics and Quantum Electronics, 51, 7.

1. A computing system for processing electromagnetic (EM) signals, the computing system comprising:
an interface that receives raw data indicative of a time rate of change of a magnetic field as recorded with a receiver coil while airborne, wherein the magnetic field includes a primary source excitation; and
a processor connected to the interface and configured to,
calculate a rotation of the receiver coil relative to a desired orientation;
derotate the raw EM data based on the rotation of the receiver coil relative to the desired orientation and on the primary source excitation, to obtain derotated EM data; and
generate an image of a surveyed subsurface based on the derotated EM data.

2. The computing system of claim 1, wherein the primary source excitation is a primary magnetic field generated by an airborne transmitter coil.

3. The computing system of claim 1, wherein the primary source excitation includes naturally occurring random fluctuations of the earth's electromagnetic field.

4. The computing system of claim 1, wherein the primary source excitation is a magnetic field generated by a stationary transmitter located at some distance from the receiver coil.

5. The computing system of claim 1, wherein the receiver coil is a magnetometer for measuring the magnetic field.

6. The computing system of claim 1, wherein the derotation reduces noise associated with a modulation of a secondary signal generated by the primary source excitation, at the primary source excitation frequency and its odd harmonics.

7. The computing system of claim 1, wherein the derotation reduces noise generated by a modulation of a secondary signal generated by the primary source excitation, at a frequency of the receiver coil's rotation.

8. The computing system of claim 1, wherein a frequency of the primary source excitation is about 30 Hz.

9. The computing system of claim 1, wherein the processor is configured to calculate the rotation based on,
measurements indicative of an orientation or position of the receiver coil, and
measurements indicative of an orientation of the primary source excitation.

10. The computing system of claim 1, further comprising:
a transmitter coil;
the receiver coil; and
a position or rotation device that measures a position or rotation of the receiver coil relative to the primary source excitation.

11. A method for processing electromagnetic (EM) signals,
the method comprising:
receiving raw data indicative of a time rate of change of a magnetic field as recorded with a receiver coil while airborne, wherein the magnetic field includes a primary source excitation;
calculating a rotation of the receiver coil relative to a desired orientation;
derotating the raw EM data based on the rotation of the receiver coil relative to the desired orientation and on the primary source excitation, to obtain derotated EM data; and
generating an image of a surveyed subsurface based on the derotated EM data.

12. The method of claim 11, wherein the primary source excitation is a primary magnetic field generated by an airborne transmitter coil.

13. The method of claim 11, wherein the primary source excitation includes naturally occurring random fluctuations of the earth's electromagnetic field.

14. The method of claim 11, wherein the primary source excitation is a magnetic field generated by a stationary transmitter located at some distance from the receiver coil.

15. The method of claim 11, wherein the receiver coil is a magnetometer for measuring the magnetic field.

16. The method of claim 11, wherein the step of derotation reduces noise associated with a modulation of a secondary signal generated by the primary source excitation, at the primary source excitation frequency and its odd harmonics.

17. The method of claim 11, wherein the step of derotation reduces noise generated by a modulation of a secondary signal generated by the primary source excitation, at a frequency of the receiver coil's rotation.

18. The method of claim 11, wherein a frequency of the primary source excitation is about 30 Hz.

19. The method of claim 11, further comprising:
measuring an orientation or position of the receiver coil, and
measuring an orientation of the primary source excitation.

20. A non-transitory computer readable medium including computer executable instructions, wherein the instructions, when executed by a computer, implement a method for processing electromagnetic (EM) signals, the method comprising:
receiving raw data indicative of a time rate of change of a magnetic field as recorded with a receiver coil while airborne, wherein the magnetic field includes a primary source excitation;
calculating a rotation of the receiver coil relative to a desired orientation;
derotating the raw EM data based on the rotation of the receiver coil relative to the desired orientation and on the primary source excitation, to obtain derotated EM data; and
generating an image of a surveyed subsurface based on the derotated EM data.
